(19) United States
(12) Patent Application Publication
(10) Pub. No.: US 2003/0164716 A1
(43) Pub. Date: Sep. 4, 2003

(54) Alignment apparatus for an IC test handler

(76) Inventors: Yi-Chang Hsieh, Hsinchu (TW); Mu-Sheng Liao, Hsinchu (TW); Ching-Jung Huang, Hsinchu (TW)

Correspondence Address: BAKER & BOTTS, 30 ROCKEFELLER PLAZA, NEW YORK, NY, 10112

(21) Appl. No.: 10/090,309

(22) Filed: Mar. 4, 2002

(51) Int. Cl. G01R 31/02

(52) U.S. Cl. 324/758

(57) ABSTRACT

An alignment apparatus for an integrated circuit (IC) test handler is disclosed. The alignment apparatus of the present invention installs a plurality of first guide pins and a plurality of second guide pins on a load board stiffener, and the first and second guide pins penetrate a load board and a surface mount matrix (SMM) frame member used for fastening a SMM sequentially from the backsides of load board and SMM frame member. When an IC device packaged by the ball grid array (BGA) method is in an electrical test, the present invention can shorten the working distance of a test arm of the IC test handler for enhancing the stability of testing process, thereby promoting the testing yield. Furthermore, with a shorter working distance, the output force from the test arm is smaller, so that the force acted on solder balls located at the bottom of the BGA device is smaller, thereby prolonging the service life of SMM contacting the solder balls.

### FIELD OF THE INVENTION

The present invention relates to an alignment apparatus for an integrated circuit (IC) test handler, and more particularly, to an alignment apparatus used for an IC test handler by using guide pins penetrating a load board and a surface mount matrix (SMM) frame member sequentially from the backsides of load board and SMM frame member.

### BACKGROUND OF THE INVENTION

A ball grid array (BGA) packaging method is to evenly dispose solder balls on part or all of the bottom area of a package, thereby increasing the pin count of IC device without the problem of small pitch. Hence, the BGA packaging method is widely used in fabricating a high pin-count IC device.

When a BGA device is completely fabricated, the BGA device has to pass an electrical test so as to ensure its quality, and the electrical test for the BGA device usually is performed with a handler that is mainly utilized for picking and placing the BGA device, and for classifying the pass/fail devices into bins. Referring to FIG. 1, FIG. 1 is a schematic diagram showing a conventional alignment apparatus for an IC test handler, wherein the conventional alignment apparatus is mounted on a load board. A handler (not shown) picks up a BGA device from an IC carrier (not shown), and then moves the BGA device to the area above a socket base 110, and thereafter the BGA device is pressed by a test arm of the handler to make contact with a load board 100 via a SMM 140 for performing an electrical test. Since the handler is operated in an automation mode, the alignments for positioning the handler and the BGA are quite important, or the problems, such as test errors, and damages of the BGA device and the test equipments, are very likely to occur. Therefore, an alignment apparatus for an IC test handler is frequently installed for aligning the positions of the handler and the BGA device, manly utilizing two sets of guide pins for respectively checking the alignments of the handler and the BGA device.

Please continue to refer to FIG. 1. The conventional alignment apparatus for an IC test handler is mainly composed of a socket base 110, and a pair of first guide pins 120 and a pair of second guide pins 130 are fixed on the socket base 110, wherein the first guide pins 120 are used for aligning the position of the handler, and the second guide pins 130 are for aligning that of the BGA device. An opening 145 is located at the central area of the socket base 110, and a SMM 140 is fixed at the backside of the opening 145. In the conventional alignment apparatus for an IC test handler, the load board 100 having the layout of testing circuit is mounted on a testing machine (not shown), wherein the lower surface of load board 100 has been installed electrical circuit components. Then, the socket base 110 is fixed on the load board's upper surface on which no electrical circuit components are installed, and the socket base's surface having no SMM 140 faces upward for receiving a BGA device (not shown). Thus, the SMM 140 is located between the BGA device and the load board 100, thereby preventing solder balls located at the bottom of BGA from directly contacting the load board 100, so that the solder balls and the load board 100 are damaged while the BGA device is pressed by the test arm.

When the BGA device is in the electrical test, the pressing motion from the test arm makes the solder balls located at the bottom of the BGA device endure a certain degree of force, and the force acted on the SMM affects the service life of SMM. In other words, if the SMM receives too much pressing force, the service life of SMM will be shortened accordingly. Furthermore, the magnitude of output force from the test arm is proportional to the working distance of test arm, i.e. the longer the working distance of test arm, the bigger the output force from the test arm. Additionally, the longer working distance will reduce the stability of testing process, thus resulting in a poor testing yield.

However, such as shown in FIG. 1, the conventional alignment apparatus for an IC test handler is mounted on the top of the load board 100, and the working distance of test arm becomes longer due to the addition of the height of socket base 110. With the longer working distance the test arm has to employ more force in order to pass the test. Just as the aforementioned description, the longer test arm's working distance and the stronger output force caused thereby result in a poor testing process stability and a low testing yield, and furthermore shorten the service life of SMM, thus increasing the production cost.

Hence, there is an urgent need in developing an alignment apparatus for an IC test handler to replace the conventional alignment apparatus to shorten the working distance of test arm for enhancing the testing process stability, and also reduce the force acted on the SMM, thereby promoting the testing yield and prolonging the service life of SMM.

### SUMMARY OF THE INVENTION

Just as described above, the conventional alignment apparatus for an IC test handler is mounted on the top of the load board, and the working distance of test arm is longer due to the addition of the height of socket base, thus affecting the stability of testing process and lowering the testing yield. Furthermore, the longer working distance demands more output force from the test arm, thus increasing more pressing force acted on a SMM via solder balls located at the bottom of a BGA device, so that the SMM service life is shortened.

Therefore, it is a main object of the present invention to provide an alignment apparatus for an IC test handler to replace the conventional alignment apparatus. The alignment apparatus of the present invention does not need to utilize a socket base for installing guide pins so as to shorten the working distance of test arm for enhancing the stability of testing process. Furthermore, with a shorter working distance obtained, the output force from the test arm can be reduced thereby promoting the testing yield and prolonging the service life of SMM.

In accordance with the aforementioned object of the present invention, the present invention provides an alignment apparatus for an IC test handler. The alignment apparatus of the present invention installs a plurality of first guide pins and a plurality of second guide pins on a load board stiffener, for example, 2 first guide pins and 2 second guide pins. These first guide pins and second guide pins are inserted to penetrate the load board and a SMM frame member sequentially from their backsides, wherein the first guide pins are used for aligning the IC test handler, and the second guide pins are for aligning an IC device, such as a BGA device. The central area of the SMM frame member has an opening for the SMM to be installed at the backside of the opening, whereby the SMM frame member can fasten the SMM.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic diagram showing a conventional alignment apparatus for an IC test handler, wherein the conventional alignment apparatus is mounted on a load board; and

FIG. 2 is a schematic assembly diagram of an alignment apparatus for an IC test handler, according to a preferred embodiment of the present invention.

### DETAILED DESCRIPTION OF THE PREFERRED EMBODIMENT

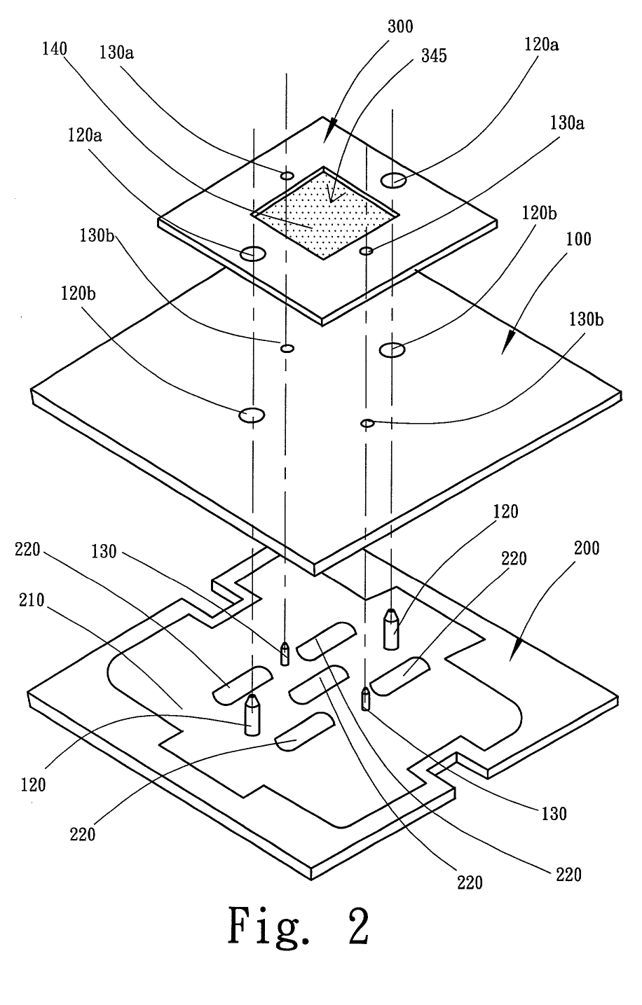

The present invention discloses an alignment apparatus for an IC test handler. The IC test handler is mainly utilized for picking and placing the IC device, such as a BGA device, and the handler can be, for example, the one of model no. NS5000 manufactured by Seiko Epson Corporation, Japan. Referring to FIG. 2, FIG. 2 is a schematic assembly diagram of an alignment apparatus for an IC test handler, according to a preferred embodiment of the present invention. The alignment apparatus of the present invention for an IC test handler comprises: a load board stiffener 200; a plurality of first guide pins 120 (for example, 2 first guide pins) fixed on the load board stiffener 200 for aligning the IC test handler; a plurality of second guide pins 130 (for example, 2 second guide pins) fixed on the load board stiffener 200 for aligning an IC deice, for example, a BGA device; a plurality of first guide pin holes 120b corresponding to the first guide pins 120, and a plurality of second guide pins holes 130b corresponding to the second guide pins 130, wherein the first guide pins holes 120b and the second guide pins holes 130b are installed on the load board 100 for allowing the first guide pins 120 and the second guide pins 130 to penetrate the load board 100 from a surface thereof having electrical circuit components toward the other surface opposite to the former surface, when the load board 100 is mounted on the load board stiffener 200; and a SMM frame member 300 mounted the surface having no electrical circuit components, wherein an opening 345 is located in the central area of the SMM frame member 300 for installing a SMM 140 at one side of the opening 345 so as to expose the SMM 140. The SMM frame member 145 is mainly used for fastening the SMM 140, and further has a plurality of first SMM holes 120a corresponding to the fist guide pins 120 and a plurality of second SMM holes 130a corresponding to the second guide pins 130, whereby the first guide pins 120 and the second guide pins 130 can penetrate the SMM frame member 145 from a surface having the SMM 140 toward the opposite surface. Moreover, the load board stiffener further comprises: at least one first depression area 210 and at least one second depression area 220, wherein the first depression area 210 is shallower than the second depression area 220 for accommodating smaller electrical circuit components located at the bottom of the load board 100, and the second depression area 220 is deeper thereby accommodating bigger electrical circuit components. The first depression area 210 can be a bigger area for containing the second depression area 220.

It is noted that all the constituents of the present invention as shown in FIG. 2 are merely stated as an example for explanation regarding their numbers, shapes and sizes, etc. The present can be further varied and adjusted according the actual situations. Therefore. The present invention is not limited thereto.

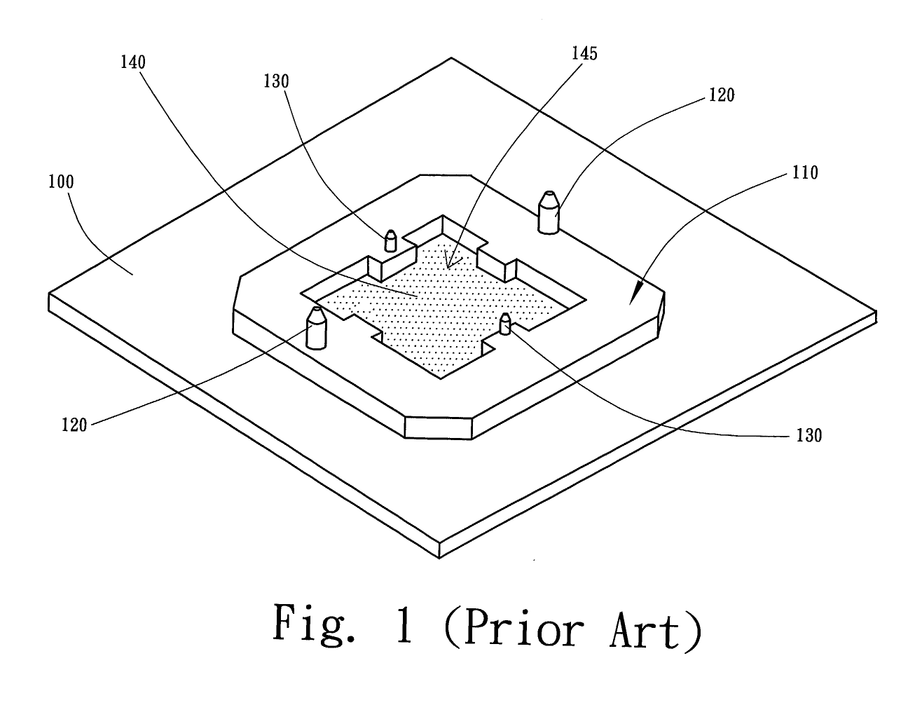

Please continue to refer to FIG. 2. As shown in FIG. 2, when the alignment apparatus of the present invention for an IC test handler is assembled on the load board 100, since no socket base 110 with a bigger thickness as shown in FIG. 1 is used, and the SMM frame member 140 with a smaller thickness is used instead, the working distance of the test arm is shortened greatly, for example, by about 8 mm. On the other hand, since the working distance is much shorter, the output force from the test arm is reduced accordingly, so that the force acted on the solder balls located at the bottom of the BGA device is also greatly reduced. Certainly, the reduction of the force on the solder balls leads to a much smaller pressing force acted on the SMM, when the solder balls are pressed on the SMM. For example, a chipset, model no. 730 made by Silicon Integrated Systems Corporation, Taiwan, has 672 solder balls. When the model no. 730 chipset is in an electrical test with the use of conventional alignment apparatus as shown in FIG. 1, each of the solder balls has to endure about 45 g force in order to pass the test, and the force in total on all 672 solder balls is about 30 kg. When the same chipset is in test with the alignment apparatus of the present invention as shown in FIG. 2, each of the solder balls only has to endure about 32 g and can pass the test. Therefore, averagely speaking, the force acted on each solder ball is reduced about 13 g, which is about ⅓ of the original force 45 g. Hence, the force pressed on the SMM is also reduced, whereby it is estimated that the service life of SMM can last ⅓ longer than that using the conventional alignment apparatus.

Hence, an advantage of the present invention is to provide an alignment apparatus for an IC test handler, which can totally replace the conventional alignment apparatus. For the present invention does not need to use a socket base to install first and second guide pins, the working distance of a test arm can then be shorten greatly, thus demanding a smaller output force from the test arm. Therefore, the alignment. apparatus of the present invention for an IC test handler can promote the testing yield and prolong the service life of SMM.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. An alignment apparatus for an integrated circuit (IC) test handler, comprising:
a load board stiffener;
a plurality of first guide pins, wherein said plurality of first guide pins are fixed on said load board stiffener for aligning said IC test handler;
a plurality of second guide pins, wherein said plurality of second guide pins are fixed on said load board stiffener for aligning an IC device, said plurality of first guide pins and said plurality of second guide pins penetrating a load board toward from a lower surface of said load board toward an upper surface opposite to said lower surface while said load board being mounted on the top of said load stiffener, said lower surface having a plurality of electrical circuit components; and
a surface mount matrix (SMM) frame member mounted on said upper surface of said load board for fixing a SMM, wherein said SMM is fixed on a surface of an opening located at the central area of said SMM frame member, said plurality of first guide pins and said plurality of second guide pins penetrating said SMM frame member from said surface having said SMM toward an other surface opposite to said surface.

2. The alignment apparatus for an IC test handler of claim 1, wherein said alignment apparatus for an IC test handler further comprises:
a plurality of first guide pin holes and a plurality of second guide pin holes, wherein said plurality of first guide pin holes and said plurality of second guide pin holes are implemented on said load board, said plurality of first guide pin holes corresponding to said plurality of first guide pins respectively, said plurality of second guide pin holes corresponding to said plurality of second guide pins respectively, thereby allowing said plurality of first guide pins and said plurality of second guide pins to penetrate said load board respectively from said lower surface toward said upper surface opposite to said lower surface via said plurality of first guide pin holes and said plurality of second guide pin holes while said load board being mounted on said load board stiffener.

3. The alignment apparatus for an IC test handler of claim 1, wherein said SMM frame member further comprises:
a plurality of first SMM holes and a plurality of second SMM holes, wherein said plurality of first SMM holes correspond to said plurality of first guide pins respectively, and said plurality of second SMM holes corresponds to said plurality of second guide pins respectively, thereby allowing said plurality of first guide pins and said plurality of second guide pins to penetrate said SMM frame member respectively from said surface having said SMM toward said other surface opposite to said surface via said plurality of first SMM holes and said plurality of second SMM holes.

4. The alignment apparatus for an IC test handler of claim 1, wherein the number of said plurality of first guide pins is 2.

5. The alignment apparatus for an IC test handler of claim 1, wherein the number of said plurality of second guide pins is 2.

6. The alignment apparatus for an IC test handler of claim 1, wherein said load board stiffener further comprises:
at least one first depression area and at least one second depression area for accommodating said plurality of electrical circuit components located at said lower surface of said load board.

7. The alignment apparatus for an IC test handler of claim 6, wherein said at least one second depression area is located inside said at least one first depression area.

8. The alignment apparatus for an IC test handler of claim 6, wherein said at least one second depression area has a deeper depth than said at least one first depression area, thereby accommodating a plurality of bigger electrical circuit components.

9. The alignment apparatus for an IC test handler of claim 1, wherein said IC device is a ball grid array (BGA) device.

10. The alignment apparatus for an IC test handler of claim 1, wherein said handler is a model no. NS500 handler manufactured by Seiko Epson Corporation, Japan.

11. An alignment apparatus for an IC test handler, comprising:
a load board stiffener, wherein said load board stiffener further comprises:
at least one first depression area and at least one second depression are, wherein said least one second depression area is located inside said at least one first depression area;
a plurality of first guide pins, wherein said plurality of first guide pins are fixed on said load board stiffener for aligning said IC test handler;
a plurality of second guide pins, wherein said plurality of second guide pins are fixed on said load board stiffener for aligning an IC device;
a plurality of first guide pin holes and a plurality of second guide pin holes, wherein said plurality of first guide pin holes and said plurality of second guide pin holes are implemented on said load board that is mounted on said load board stiffener, said plurality of first guide pin holes corresponding to said plurality of first guide pins respectively, said plurality of second guide pin holes corresponding to said plurality of second guide pins respectively, thereby allowing said plurality of first guide pins and said plurality of second guide pins to penetrate said load board toward from a lower surface of said load board toward an upper surface opposite to said lower surface via said plurality of first guide pin holes and said plurality of second guide pin holes, said lower surface having a plurality of electrical circuit components; and
a surface mount matrix (SMM) frame member mounted on said upper surface of said load board for fixing a SMM, wherein said SMM is fixed on a surface of an opening located at the central area of said SMM frame member, said SMM frame member having a plurality of first SMM holes and a plurality of second SMM holes, said plurality of first SMM holes corresponding to said plurality of first guide pins respectively, said plurality of second SMM holes corresponding to said plurality of second guide pins respectively, thereby allowing said plurality of first guide pins and said plurality of second guide pins to penetrate said SMM frame member respectively from said surface having said SMM toward an other surface opposite to said surface via said plurality of first SMM holes and said plurality of second SMM holes.

12. The alignment apparatus for an IC test handler of claim 11, wherein the number of said plurality of first guide pins is 2.

13. The alignment apparatus for an IC test handler of claim 11, wherein the number of said plurality of second guide pins is 2.

14. The alignment apparatus for an IC test handler of claim 11, wherein said at least one second depression area has a deeper depth than said at least one first depression area, thereby accommodating a plurality of bigger electrical circuit components.

15. The alignment apparatus for an IC test handler of claim 11, wherein said IC device is a BGA device.

16. The alignment apparatus for an IC test handler of claim 11, wherein said handler is a model no. NS5000 handler manufactured by Seiko Epson Corporation, Japan.
